(19) United States
(12) Patent Application Publication
(10) Pub. No.: US 2024/0025802 A1
(43) Pub. Date: Jan. 25, 2024

(54) SILICA GLASS POROUS BODY AND MANUFACTURING METHOD THEREFOR

(71) Applicant: AGC Inc., Tokyo (JP)

(72) Inventor: Kazuya SASAKI, Fukushima (JP)

(73) Assignee: AGC Inc., Tokyo (JP)

(21) Appl. No.: 18/479,859

(22) Filed: Oct. 3, 2023

Related U.S. Application Data
(63) Continuation of application No. PCT/JP2022/016897, filed on Mar. 31, 2022.

(30) Foreign Application Priority Data
Apr. 7, 2021 (JP) 2021-065433

(51) Int. Cl. C03C 11/00; C03B 19/14

(52) U.S. Cl. CPC C03C 11/00; C03B 19/1453

(57) ABSTRACT

An object of the present invention is to provide a technique capable of obtaining a shower plate having cleaning resistance without machining. The present invention relates to a silica glass porous body having a plurality of pores, in which the plurality of pores includes a non-communication pore and a communication pore, and the pores have an average pore size, obtained by mercury intrusion porosimetry, of 10 μm to 150 μm.

### CROSS-REFERENCE TO RELATED APPLICATIONS

This is a continuation of International Application No. PCT/JP2022/016897 filed on Mar. 31, 2022, and claims priority from Japanese Patent Application No. 2021-065433 filed on Apr. 7, 2021, the entire content of which is incorporated herein by reference.

### TECHNICAL FIELD

The present invention relates to a silica glass porous body and a method for producing the same.

### BACKGROUND ART

Manufacturing processes of a semiconductor device include an etching process and a chemical vapor deposition (CVD) process, and a shower plate is usually used to supply a source gas in these processes.

The shower plate is manufactured by, for example, machining a plate-shaped member made of glass or ceramics to form a large number of straight tubular through holes. Each through hole is formed to have a diameter of about several hundred micrometers to several millimeters.

However, forming the through holes by machining as described above has a problem that the machining is highly difficult, the shower plate is likely to be damaged during the machining, and cost tends to be high.

Therefore, a shower plate in which through holes are formed without machining has been proposed, for example, as in Patent Literature 1.

Patent Literature 1 discloses a shower plate made of an amorphous silica porous body. A slurry containing silica particles having an average particle size of 20 μm to 100 μm and within a range of ±50% of the average particle size is prepared, molded, and fired, so that a porous body, which is an incomplete sintered body, is obtained in which a contact length in at least one point between adjacent silica particles is 1/15 to ¾ of a particle size of the silica particles, and a communication hole having an average pore size of 5 μm to 25 μm is present.
Patent Literature 1: JP2013-147390A

### SUMMARY OF INVENTION

By the way, in an etching process and a CVD process, reaction by-products and the like generated by various chemical reactions may deposit on a shower plate and become a dust source of particles. The generated particles may adhere to a substrate and reduce a yield.

Therefore, the shower plate is periodically cleaned to reduce particle generation. Chemical solutions such as aqua regia, hydrofluoric acid (fluoric acid), and a mixed solution of fluoric acid and nitric acid are usually used for cleaning.

However, when the shower plate described in Patent Literature 1 is cleaned with a chemical solution, bonding portions between the adjacent silica particles are easily etched, and the silica particles is likely to drop off. In this case, a volume of the shower plate is reduced by an etched volume and a volume of the dropped silica particles themselves, so that the volume is significantly reduced. Furthermore, the dropped silica particles may remain inside the shower plate and impede gas permeation. Therefore, the shower plate described in Patent Literature 1 is not suitable for cleaning and repeated use because properties of the shower plate may change greatly due to cleaning.

Therefore, it is difficult to obtain a shower plate having cleaning resistance without machining.

An object of the present invention is to provide a technique capable of obtaining a shower plate having cleaning resistance without machining.

The present invention relates to the following [1] to [7].

[1] A silica glass porous body having a plurality of pores, in which the plurality of pores includes a non-communication pore and a communication pore, and the pores have an average pore size, obtained by mercury intrusion porosimetry, of 10 μm to 150 μm.

[2] The silica glass porous body according to [1], having a gas permeability coefficient, obtained by using a perm porometer, of 0.01 μm² to 10 μm².

[3] The silica glass porous body according to [1] or [2], having a specific surface area, obtained by a BET method, of 0.01 m²/g to 0.1 m²/g.

[4] The silica glass porous body according to any one of [1] to [3], having a bulk density of 0.3 g/cm³ to 2 g/cm³.

[5] The silica glass porous body according to any one of [1] to [4], in which a content of each of metal impurities including lithium (Li), aluminum (Al), chromium (Cr), manganese (Mn), nickel (Ni), copper (Cu), titanium (Ti), cobalt (Co), zinc (Zn), silver (Ag), cadmium (Cd), lead (Pb), sodium (Na), magnesium (Mg), potassium (K), calcium (Ca), and iron (Fe) is 0.5 ppm by mass or less.

[6] A shower plate including the silica glass porous body according to any one of [1] to [5].

[7] A method for producing a silica glass porous body having a plurality of pores, in which the plurality of pores includes a non-communication pore and a communication pore, and the pores have an average pore size, obtained by mercury intrusion porosimetry, of 10 μm to 150 μm, the method including: depositing silica particles generated by flame hydrolysis of a silicon compound to obtain a soot body; densifying the soot body in an inert gas atmosphere to obtain a silica glass dense body; and making the silica glass dense body porous under a condition of at least a lower pressure or a higher temperature than that when the silica glass dense body is obtained.

According to the present invention, a shower plate having cleaning resistance can be obtained without machining.

### BRIEF DESCRIPTION OF DRAWINGS

FIG. 1 is a diagram schematically illustrating a cut surface of an arbitrary part of a silica glass porous body according to an embodiment.

FIG. 2A and FIG. 2B are diagrams showing a member obtained by cutting out an arbitrary part of the silica glass porous body according to the embodiment in a rectangular parallelepiped shape, where FIG. 2A is a perspective view of the member, and FIG. 2B is a cross-sectional view taken along the line X-X′ of FIG. 2A.

FIG. 3 is a flowchart showing a method for producing the silica glass porous body according to the embodiment.

FIG. 4 is an optical microscope image in which a cut surface of a silica glass porous body according to Example 1 was optically polished and captured.

FIG. 5 is an SEM image of a soot body according to Example 8.

FIG. 6 is an SEM image of a sintered body according to Example 9.

### DESCRIPTION OF EMBODIMENTS

Hereinafter, an embodiment according to the present invention (hereinafter, simply referred to as the present embodiment) is described in detail by using drawings. In the drawings, positional relationships such as top, bottom, left, and right are based on positional relationships shown in the drawings unless otherwise specified. Dimensional ratios in the drawings are not limited to shown ratios. In addition, in the specification, the term “to” that is used to express a numerical range includes numerical values before and after the term as a lower limit value and an upper limit value of the range, respectively. The lower limit value and the upper limit value include a rounding range.

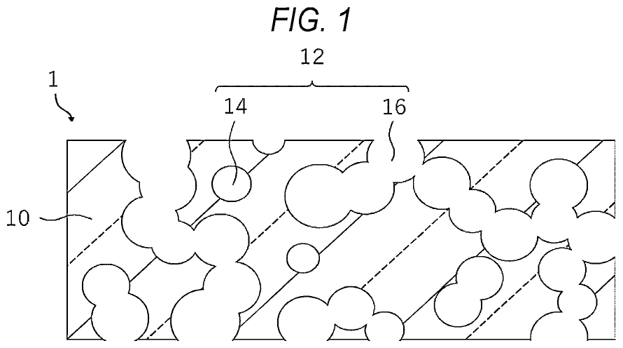

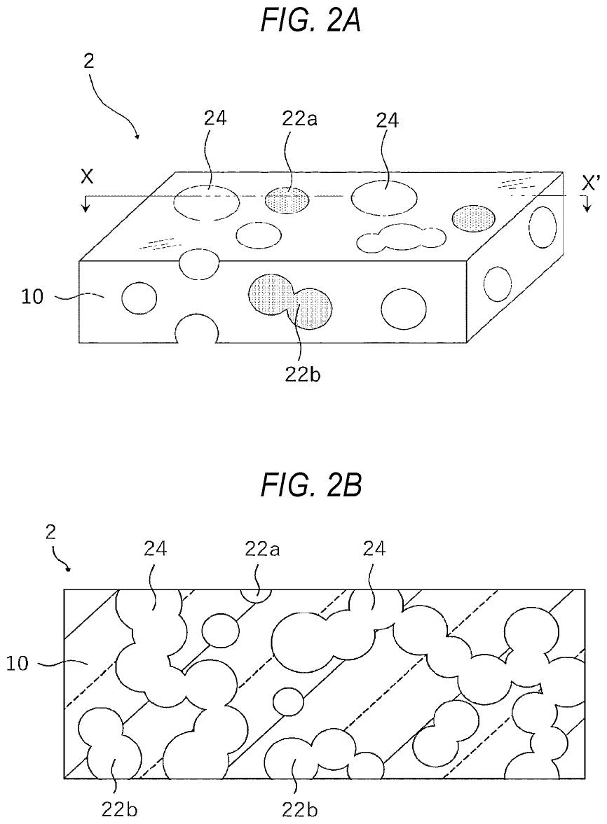

First, a structure of a silica glass porous body 1 according to the present embodiment will be described with reference to FIGS. 1 and 2.

FIG. 1 is a diagram schematically illustrating a cut surface of an arbitrary part of the silica glass porous body 1. The silica glass porous body 1 includes a silica glass portion 10 and pores 12.

The silica glass portion 10 mainly contains amorphous silicon oxide (SiO₂) and is transparent. A density of the silica glass portion 10 is about 2.2 g/cm³. The silica glass portion 10 may contain different elements in addition to SiO₂ for an object of controlling properties of the silica glass portion 10.

The pores 12 include non-communication pores 14 and communication pores 16.

The non-communication pores 14 are dispersed substantially uniformly in the silica glass porous body 1 and contain gas therein. The non-communication pore 14 has a substantially spherical shape.

The communication pores 16 are formed by communicating the non-communication pores 14 adjacent to each other. FIG. 1 depicts an aspect of two-dimensional communication, but it is natural that three-dimensional communication may occur. At least some of the pores 12 of the silica glass porous body 1 form the communication pores 16.

FIG. 2A is a perspective view of a member 2 obtained by cutting out an arbitrary part of the silica glass porous body 1 in a rectangular parallelepiped shape, and FIG. 2B is a cross-sectional view taken along the line X-X′ of FIG. 2A. The member 2 made of the silica glass porous body 1 includes the silica glass portion 10, non-through holes 22a and 22b, and through holes 24.

The non-through hole is formed by a pore that does not penetrate from any one surface to another surface of the member. Here, even if the pores communicate with each other, there is a case where the communicated pores do not penetrate. Therefore, the non-through holes are formed by the communication pores or non-communication pores that do not penetrate from any one surface to the other surface of the member. As illustrated in FIG. 2B, the non-through hole 22a is formed by the non-communication pore that does not penetrate, and the non-through hole 22b is formed by the communication pore that does not penetrate. Appearances of the non-through holes 22a and 22b in the surface of the member 2 have a substantially circular shape or a shape formed by connecting the substantially circular shapes.

The through hole 24 is formed by the communication pore that penetrates from any one surface to another surface of the member 2. An appearance of the through hole 24 in the surface of the member 2 has a substantially circular shape or a shape formed by connecting the substantially circular shapes. Since the through hole 24 allows liquid or gas to pass through, the member 2 can be suitably used as a shower plate used in a semiconductor manufacturing apparatus. An use of the member 2 is not limited to the shower plate, and the member 2 can be applied to various uses within a range in which properties of the silica glass porous body 1 described in the present specification work effectively.

Next, the properties of the silica glass porous body 1 according to the present embodiment will be described.

The lower limit of the average pore size of the pores 12 is 10 μm, and preferably 25 μm, and the upper limit thereof is 150 μm, and preferably 125 μm. In the case where the average pore size is 10 μm or more, when the member 2 is used as a shower plate, a pressure loss when the gas passes through the through hole 24 formed by the pores 12 is reduced, and the gas can be uniformly supplied. In the case where the average pore size is 150 μm or less, occurrence of abnormal discharge can be sufficiently prevented when the member 2 is used as a shower plate. The average pore size of the pores 12 can be obtained by a mercury intrusion porosimetry.

The lower limit of the gas permeability coefficient of the silica glass porous body 1 is 0.01 μm², preferably 0.1 μm², and more preferably 0.2 μm², and the upper limit thereof is 10 μm², preferably 5 μm², and more preferably 4 μm². In the case where the gas permeability coefficient is within this range, the member 2 can be suitably used as a shower plate. The gas permeability coefficient of the silica glass porous body 1 can be obtained by using a perm porometer.

The lower limit of the specific surface area of the silica glass porous body 1 is 0.01 m²/g, and preferably 0.03 m²/g, and the upper limit thereof is 0.1 m²/g. In the case where the specific surface area is within this range, the member 2 can be suitably used for cleaning when used as a shower plate. The specific surface area of the silica glass porous body 1 can be obtained by a BET method.

The lower limit of the bulk density of the silica glass porous body 1 is 0.3 g/cm³, and preferably 0.6 g/cm³, and the upper limit thereof is 2 g/cm³, and preferably 1.6 g/cm³. In the case where the bulk density is 0.3 g/cm³ or more, a sufficient strength of the silica glass porous body 1 can be obtained. In the case where the bulk density is 2 g/cm³ or less, the silica glass porous body 1 contains enough pores 12, and the member 2 can be suitably used as a shower plate.

In the silica glass portion 10, a content of each of metal impurities including lithium (Li), sodium (Na), magnesium (Mg), aluminum (Al), potassium (K), calcium (Ca), chromium (Cr), manganese (Mn), iron (Fe), nickel (Ni), copper (Cu), titanium (Ti), cobalt (Co), zinc (Zn), silver (Ag), cadmium (Cd), and lead (Pb) is 0.5 ppm by mass or less, and preferably 0.1 ppm by mass or less. In the case where the content of each of the metal impurities is 0.5 ppm by mass or less, the member 2 can be suitably used as a member used in a semiconductor manufacturing apparatus. In the specification, ppm means parts per million and ppb means parts per billion.

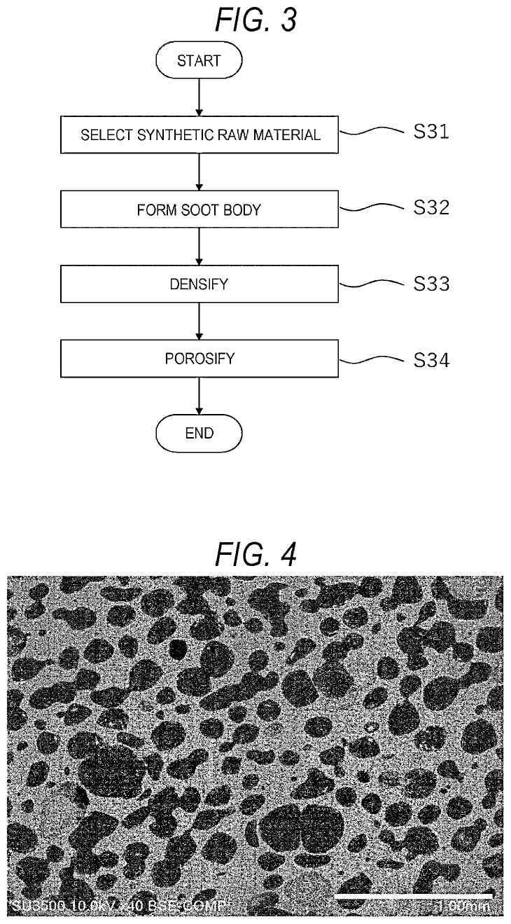

Next, a method for producing the silica glass porous body 1 according to the present embodiment will be described with reference to FIG. 3.

In the present embodiment, a vapor-phase axial deposition (VAD) method is used as a method for synthesizing silica glass, but the method for producing may be changed as appropriate as long as effects of the present invention are exhibited.

As shown in FIG. 3, the method for producing the silica glass porous body 1 includes steps S31 to S34.

In step S31, a synthetic raw material for the silica glass is selected. The synthetic raw material for the silica glass is not particularly limited as long as the synthetic raw material is a gasifiable silicon-containing raw material, and examples thereof typically include halogen-containing silicon compounds such as silicon chlorides (for example, SiCl₄, SiHCl₃, SiH₂Cl₂, and SiCH₃Cl) and silicon fluorides (for example, SiF₄, SiHF₃, and SiH₂F₂), and halogen-free silicon compounds such as alkoxysilane represented by RₙSi(OR)₄₋ₙ, (R: an alkyl group having 1 to 4 carbon atoms, n: an integer of 0 to 3) and (CH₃)₃Si—O—Si(CH₃)₃.

Next, in step S32, the synthetic raw material is subjected to flame hydrolysis at a temperature of 1000° C. to 1500° C. to generate silica particles, and the generated silica particles are sprayed and deposited on a rotating base material to obtain a soot body. In the soot body, the silica particles are partly sintered together.

Although not shown, for an object of controlling electrical properties, the soot body may be heat-treated in a vacuum atmosphere to dehydrate, to thereby reduce an OH group concentration. In this case, the temperature during the heat treatment is preferably 1000° C. to 1300° C., and the treatment time is preferably 1 hour to 240 hours.

Next, in step S33, the soot body is subjected to a high-temperature and high-pressure treatment in an inert gas atmosphere, whereby sintering of the silica particles in the soot body progresses and densification progresses, and as a result, a silica glass dense body is obtained. The silica glass dense body is a transparent silica glass containing almost no pores or an opaque silica glass containing minute pores. In this case, the temperature during the high-temperature and high-pressure treatment is preferably 1200° C. to 1700° C., the pressure is preferably 0.01 MPa to 200 MPa, and the treatment time is preferably 10 hours to 100 hours.

In step S33, the inert gas is dissolved in the silica glass. The inert gas is typically helium (He), neon (Ne), argon (Ar), krypton (Kr), xenon (Xe), nitrogen gas (N₂), or a mixed gas containing at least two of these, and is preferably Ar, although details will be described later. It is generally known that solubility of an inert gas in the silica glass tends to decrease as a partial pressure of the inert gas in the atmosphere decreases or as the temperature of the silica glass increases.

Next, in step S34, the silica glass dense body is subjected to a high-temperature and low-pressure treatment, whereby the inert gas dissolved in the silica glass foams and the pores contained in the silica glass dense body thermally expands, so that porosification progresses, and as a result, the silica glass porous body 1 having the pores 12 is obtained. In this case, the temperature during the high-temperature and low-pressure treatment is preferably 1300° C. to 1800° C., the pressure is preferably 0 Pa to 0.1 MPa, and the treatment time is preferably 1 minute to 20 hours. In the case where the treatment time is within 20 hours, there is no possibility that the pores 12 are closed due to excessive heating.

Here, a foaming mechanism will be described. As described above, solubility of the inert gas in the silica glass tends to decrease as the partial pressure of the inert gas in the atmosphere decreases or as the temperature of the silica glass increases. Therefore, in step S34, when the treatment is performed at a lower pressure or a higher temperature than that in step S33, dissolved amount of the inert gas may become supersaturated, and in this case, foaming will occur in the silica glass.

Considering the above-described mechanism, the foaming can occur even in the case where the temperature during the high-temperature and low-pressure treatment in step S34 is lower than the temperature during the high-temperature and high-pressure treatment in step S33, but the foaming is promoted and the porosification tends to progress in the case where the temperature is higher than the temperature in the high-temperature and high-pressure treatment in step S33.

Among the options for the inert gas described above, Ar is preferable from viewpoints that Ar is relatively inexpensive, its solubility in the silica glass is highly dependent on temperature, and the porosification is easily controlled.

The temperatures, the pressures, and the treatment times in the high-temperature and high-pressure treatment in step S33 and the high-temperature and low-pressure treatment in step S34 can be appropriately adjusted to change an amount of foam and a degree of pore expansion, so that the number, pore size, and the like of the pores 12 contained in the silica glass porous body 1 can be controlled.

### EXAMPLES

Experimental data will now be described with reference to Table 1 and FIGS. 4 to 6. In Table 1, Examples 1 to 7 are Invention Examples, and Examples 8 to 9 are Comparative Examples.

Physical property values shown in Table 1 were obtained by methods shown below.

The average pore size was obtained by mercury intrusion porosimetry in accordance with JIS-R1655: 2003. Specifically, an object to be evaluated was cut into a cylindrical shape with a diameter of 10 mm and a thickness of 5 mm, a pore size distribution was measured with a mercury porosimeter (manufactured by Micromeritics: AutoPore V9620), and a pore size when a cumulative pore volume was 50% of a total pore volume was defined as the average pore size.

The gas permeability coefficient was obtained by using a perm porometer. Specifically, the object to be evaluated was cut into a disk shape with a diameter of 25 mm and a thickness of 2 mm, set in a holder of the perm porometer (manufactured by PMI: CFP-1200AEXL), and the gas was circulated at a flow rate of 1 L/min to 200 L/min. In this case, the gas permeability coefficient (K) when ΔP=10 kPa was obtained from the following Formula (1). The air was used as the gas.

K=(μ·L·Q)/(ΔP·A) (1)

In the above Formula (1), K represents the gas permeability coefficient (unit: m²), μ represents a gas viscosity (unit: Pa·s), L represents a sample thickness (unit: m), Q represents a gas flow rate (m³/s), ΔP represents a pressure difference (unit: Pa) between a gas inlet portion and a gas outlet portion in the sample, and A represents a cross-sectional area of the sample (m²).

The specific surface area was obtained by a BET method in accordance with JIS-Z8830: 2013. Specifically, a small piece of about 1 g was cut out from the object to be evaluated, and after performing a vacuum degassing treatment at 200° C. for about 5 hours as a pretreatment, adsorption measurement of krypton (Kr) gas was performed by using a specific surface area measuring device (manufactured by Nippon Bell Co., Ltd.: BELSORP-max), and calculation was performed by using a BET formula.

The bulk density was obtained as follows. The object to be evaluated was cut into a cylindrical shape with a diameter of 10 mm and a thickness of 5 mm, and the sample mass measured by an electronic balance was divided by an apparent volume of the sample.

The weight change rate due to fluoric acid was obtained as follows. The object to be evaluated was cut into a plate with a width of 15 mm, a depth of 15 mm, and a thickness of 3 mm, followed by immersing in 5% by mass fluoric acid at room temperature for 1 hour, and a rate of change in the sample weight before and after immersion was calculated.

### Examples 1 to 7

Silicon tetrachloride (SiCl₄) was selected as the synthetic raw material for the silica glass, and subjected to flame hydrolysis to generate silica particles. The obtained silica particles were sprayed and deposited on a rotating base material to obtain a soot body. Next, the soot body was placed in a heating furnace, and the heating furnace was filled with Ar gas. A high-temperature and high-pressure treatment was performed at a predetermined temperature, pressure, and treatment time to densify the soot body, followed by returning to an atmospheric pressure and allowing to cool. The silica glass dense body obtained in this case was an opaque silica glass containing minute pores. Next, evacuation was performed, and a high-temperature and low-pressure treatment was performed at a predetermined temperature and treatment time, so that the silica glass dense body was made porous, followed by returning to the atmospheric pressure and allowing to cool. Then, the obtained silica glass porous body 1 was taken out. By arbitrary combining the temperatures, the pressures, and the treatment times in the high-temperature and high-pressure treatment and the high-temperature and low-pressure treatment, the silica glass porous bodies 1 having physical properties shown in Examples 1 to 7 in Table 1 were obtained.

FIG. 4 shows an optical microscope image in which a cut surface of the silica glass porous body 1 of Example 1 was optically polished and captured. As is clear from FIG. 4, in the silica glass porous body 1 of Example 1, substantially uniformly dispersed pores 12 existed, some of which existed as communication pores 16.

As a result of measuring the contents of the metal impurities in the silica glass porous body 1 of Example 1, Li, Al, Cr, Mn, Ni, Cu, Ti, Co, Zn, Ag, Cd, and Pb were less than 3 ppb, Na was 41 ppb, Mg was 8 ppb, K was 70 ppb, Ca was 21 ppb, and Fe was 14 ppb. The contents of the metal impurities were obtained by an inductively coupled plasma-mass spectrometer (ICP-MS) method after cutting the silica gas porous body 1 obtained as described above into an appropriate size. The silica glass porous bodies of Examples 1 to 7 all had a volume change rate of 10% or less due to fluoric acid. Therefore, it can be said that these silica glass porous bodies have a high cleaning resistance in the case of being used as a shower plate and cleaned.

### Example 8

Silicon tetrachloride (SiCl₄) was selected as the synthetic raw material for the silica glass, and subjected to flame hydrolysis to generate silica particles. The obtained silica particles were sprayed and deposited on a rotating base material to obtain a soot body.

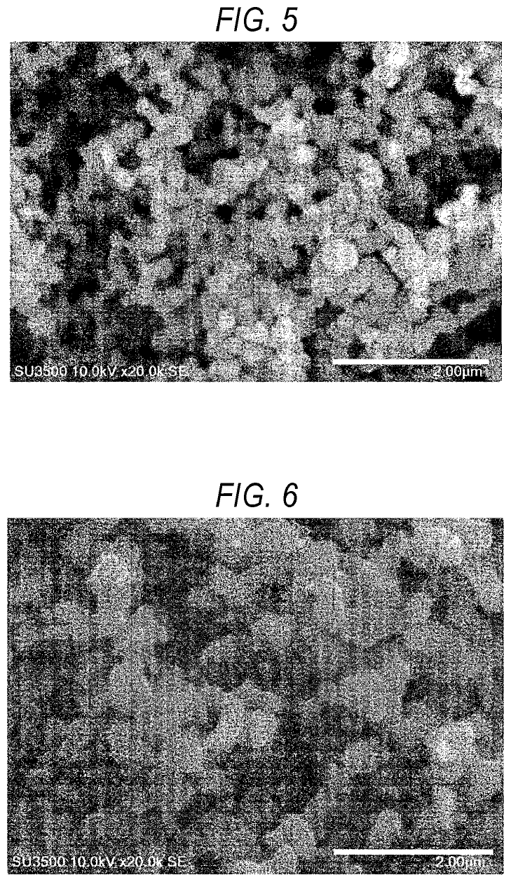

An SEM image of the soot body of Example 8 is shown in FIG. 5. As is clear from FIG. 5, the soot body of Example 8, as same as the porous body of Patent Literature 1, had a structure in which adjacent silica particles were partially sintered.

### Example 9

A soot body was obtained in the same manner as in Example 8, and then was treated in a vacuum atmosphere at 1250° C. for 50 hours to obtain a sintered body in which silica particles in the soot body were further sintered.

An SEM image of the sintered body of Example 9 is shown in FIG. 6. As is clear from FIG. 6, the sintered body of Example 9, as same as the porous body of Patent Literature 1, had a structure in which adjacent silica particles were sintered, and sintering had further progressed than the soot body of Example 8.

The soot body and sintered body of Examples 8 to 9 had a volume change rate of 30% or more due to fluoric acid. Therefore, when these product is used as a shower plate and cleaned, the volume is significantly reduced due to dropping-off of the silica particles, resulting in a large change in properties, which is clearly unsuitable for use as a shower plate.

TABLE 1

| | Average | | Specific | Bulk | Weight change |
|---|---|---|---|---|---|
| | pore size | Gas permeability | surface | density | rate due to |
| Example | [μm] | coefficient [μm²] | area [m²/g] | [g/cm³] | fluoric acid [%] |
| 1 | 74.5 | 0.71 | 0.045 | 0.94 | 1.4 |
| 2 | 90.5 | 2.76 | 0.052 | 0.52 | 2.8 |
| 3 | 69.5 | 1.35 | 0.048 | 0.77 | 1.9 |
| 4 | 40.0 | 0.15 | 0.035 | 1.35 | 0.9 |
| 5 | 94.0 | 5.58 | 0.053 | 0.48 | 5.3 |
| 6 | 21.7 | 0.06 | 0.026 | 1.61 | 0.7 |
| 7 | 126.3 | 5.18 | 0.054 | 0.36 | 6.9 |
| 8 | 0.6 | 0.02 | 5.9 | 0.51 | 65.8 |
| 9 | 0.3 | 0.01 | 4.3 | 1.26 | 30.4 |

Although the silica glass porous body and the method for producing the same according to the present invention have been described above, the present invention is not limited to the above-described embodiments and the like. Various changes, modifications, substitutions, additions, deletions, and combinations are possible within the scope of claims. These also naturally belong to the technical scope of the present invention.

The present application is based on Japanese patent application No. 2021-065433 filed on Apr. 7, 2021, and the contents thereof are incorporated herein by reference.

### REFERENCE SIGNS LIST

1 silica glass porous body
10 silica glass portion
12 pore
14 non-communication pore
16 communication pore
2 member
22a non-through hole
22b non-through hole
24 through hole

What is claimed is:

1. A silica glass porous body, comprising:
a plurality of pores, wherein
the plurality of pores includes a non-communication pore and a communication pore, and
the pores has an average pore size, obtained by mercury intrusion porosimetry, of 10 μm to 150 μm.

2. The silica glass porous body according to claim 1, having a gas permeability coefficient, obtained by using a perm porometer, of 0.01 μm² to 10 μm².

3. The silica glass porous body according to claim 1, having a specific surface area, obtained by a BET method, of 0.01 m²/g to 0.1 m²/g.

4. The silica glass porous body according to claim 1, having a bulk density of 0.3 g/cm³ to 2 g/cm³.

5. The silica glass porous body according to claim 1, wherein
a content of each of metal impurities including lithium (Li), aluminum (Al), chromium (Cr), manganese (Mn), nickel (Ni), copper (Cu), titanium (Ti), cobalt (Co), zinc (Zn), silver (Ag), cadmium (Cd), lead (Pb), sodium (Na), magnesium (Mg), potassium (K), calcium (Ca), and iron (Fe) is 0.5 ppm by mass or less.

6. A shower plate, comprising the silica glass porous body according to claim 1.

7. A method for producing a silica glass porous body having a plurality of pores, in which the plurality of pores includes a non-communication pore and a communication pore, and the pores have an average pore size, obtained by mercury intrusion porosimetry, of 10 μm to 150 μm, the method comprising:
depositing silica particles generated by flame hydrolysis of a silicon compound to obtain a soot body;
densifying the soot body in an inert gas atmosphere to obtain a silica glass dense body; and
making the silica glass dense body porous under a condition of at least a lower pressure or a higher temperature than that when the silica glass dense body is obtained.
